(19) United States
(12) Patent Application Publication
(10) Pub. No.: US 2024/0367197 A1
(43) Pub. Date: Nov. 7, 2024

(54) PIEZOELECTRIC ACTUATOR AND HAPTICS APPARATUS

(71) Applicants: Beijing BOE Technology Development Co., Ltd., Beijing (CN); BOE Technology Group Co., Ltd., Beijing (CN)

(72) Inventor: Yuju CHEN, Beijing (CN)

(21) Appl. No.: 18/032,262

(22) PCT Filed: Apr. 29, 2022
(86) PCT No.: PCT/CN2022/090502

§ 371 Date: Apr. 17, 2023

(51) Int. Cl. B06B 1/06; G08B 6/00; H10N 30/87; H10N 30/88

(52) U.S. Cl. CPC B06B 1/0648; B06B 1/0622; H10N 30/875; H10N 30/88; G08B 6/00

(57) ABSTRACT

A piezoelectric actuator includes: a base substrate, a piezoelectric device, a first heat dissipation layer, and a wire routing layer. The piezoelectric device is on the base substrate and includes at least one piezoelectric unit. Each piezoelectric unit includes a first electrode, a piezoelectric layer and a second electrode which are laminated on the base substrate in sequence. The first heat dissipation layer is on a side of the piezoelectric device facing away from the base substrate and has a first via hole. An orthographic projection of the first via hole on the base substrate overlaps an orthographic projection of the second electrode on the base substrate. The wire routing layer is on a side of the first heat dissipation layer facing away from the base substrate and includes a wire route. An end of the wire route is electrically connected to the second electrode through the first via hole.

### CROSS-REFERENCE TO RELATED APPLICATIONS

This application is a National Stage of International Application No. PCT/CN2022/090502, filed Apr. 29, 2022, the entire content of which is hereby incorporated by reference.

### FIELD

The present disclosure relates to the technical field of haptics, in particular to a piezoelectric actuator and a haptics apparatus.

### BACKGROUND

Haptics is a focus of today's technological development. Haptics can make a terminal interact with a human body through tactile sense. Haptics can be divided into two categories, i.e., vibration feedback and a haptic reproduction technology.

With a surface haptic reproduction technology, characteristics of an object can be perceived through a naked finger touching a screen, and efficient and natural interaction at a multimedia terminal can be achieved. Thus there is a great research value for the surface haptic reproduction technology which attracts extensive attention from researchers at home and abroad. Physical interpretation of the surface haptic is that surface roughness of an object interacts with the surface of the skin (fingertips), and different surface friction is formed due to different surface structures. Therefore, by controlling the surface friction, different touch/tactile senses can be simulated.

### SUMMARY

Embodiments of the present disclosure provide a piezoelectric actuator and a haptics apparatus. The solutions are as follows.

A piezoelectric actuator provided by embodiments of the present disclosure includes a base substrate, a piezoelectric device, a first heat dissipation layer, and a wire routing layer.

The piezoelectric device is located on the base substrate. The piezoelectric device includes at least one piezoelectric unit. Each piezoelectric unit includes a first electrode, a piezoelectric layer and a second electrode which are laminated on the base substrate in sequence.

The first heat dissipation layer is located on a side of the piezoelectric device facing away from the base substrate. The first heat dissipation layer has a first via hole. An orthographic projection of the first via hole on the base substrate overlaps an orthographic projection of the second electrode on the base substrate.

The wire routing layer is located on a side of the first heat dissipation layer facing away from the base substrate. The wire routing layer includes a wire route. An end of the wire route is electrically connected to the second electrode through the first via hole.

In one possible implementation, in the above piezoelectric actuator provided by the embodiments of the present disclosure, the first heat dissipation layer is of an integrated structure.

In one possible implementation, in the above piezoelectric actuator provided by the embodiments of the present disclosure, the first heat dissipation layer includes a plurality of first heat dissipation parts in one-to-one correspondence to the piezoelectric units, and each heat dissipation part has the first via hole.

In one possible implementation, the above piezoelectric actuator provided by the embodiments of the present disclosure further includes a second heat dissipation layer located between the piezoelectric unit and the base substrate.

In one possible implementation, in the above piezoelectric actuator provided by the embodiments of the present disclosure, the second heat dissipation layer is of an entire-surface structure.

In one possible implementation, in the above piezoelectric actuator provided by the embodiments of the present disclosure, the second heat dissipation layer includes a plurality of second heat dissipation parts in one-to-one correspondence to the piezoelectric units.

In one possible implementation, the above piezoelectric actuator provided by the embodiments of the present disclosure further includes a first insulating layer located between the piezoelectric device and the first heat dissipation layer. The first insulating layer has a second via hole, and an orthographic projection of the second via hole on the base substrate at least partially overlaps the orthographic projection of the first via hole on the base substrate.

In one possible implementation, in the above piezoelectric actuator provided by the embodiments of the present disclosure, the orthographic projection of the second via hole on the base substrate is substantially coincided with the orthographic projection of the first via hole on the base substrate, and the first heat dissipation layer covers a side wall of the second via hole and extends to be in contact with the second electrode.

In one possible implementation, in the above piezoelectric actuator provided by the embodiments of the present disclosure, at the same side wall of the second via hole, a contact boundary between the first heat dissipation layer and the second electrode is a first boundary, a contact boundary between the first insulating layer and the second electrode is a second boundary, and a distance between the first boundary and the second boundary is larger than 30% of a thickness of the piezoelectric layer and smaller than 60% of the thickness of the piezoelectric layer.

In one possible implementation, in the above piezoelectric actuator provided by the embodiments of the present disclosure, the first heat dissipation layer covers the side wall of the second via hole and covers the second electrode exposed by the second via hole. A part of the first heat dissipation layer covering the second electrode has at least one first via hole. The wire routing layer is electrically connected to the second electrode through the second via hole and the first via hole.

In one possible implementation, in the above piezoelectric actuator provided by the embodiments of the present disclosure, a material of the first insulating layer is an organic material.

In one possible implementation, the above piezoelectric actuator provided by the embodiments of the present disclosure further includes a third heat dissipation layer located between the first insulating layer and the piezoelectric unit. The third heat dissipation layer has a third via hole, and the third via hole, the first via hole and the second via hole at least partially overlap one another.

In one possible implementation, in the above piezoelectric actuator provided by the embodiments of the present disclosure, the third heat dissipation layer is of an integrated structure.

In one possible implementation, in the above piezoelectric actuator provided by the embodiments of the present disclosure, the third heat dissipation layer includes a plurality of third heat dissipation parts in one-to-one correspondence to the piezoelectric units, and each third heat dissipation part has the third via hole.

In one possible implementation, in the above piezoelectric actuator provided by the embodiments of the present disclosure, a material of the first heat dissipation layer is an insulating material.

When the piezoelectric actuator includes the second heat dissipation layer, a material of the second heat dissipation layer is an insulating material.

When the piezoelectric actuator includes the third heat dissipation layer, a material of the third heat dissipation layer is an insulating material.

In one possible implementation, in the above piezoelectric actuator provided by the embodiments of the present disclosure, the insulating material includes at least one of AlN, Al₂O₃ or Si₃N₄.

In one possible implementation, in the above piezoelectric actuator provided by the embodiments of the present disclosure, a thickness of the first heat dissipation layer is 300 nm-2000 nm, a thickness of the second heat dissipation layer is 300 nm-2000 nm, and a thickness of the third heat dissipation layer is 300 nm-2000 nm.

In one possible implementation, the above piezoelectric actuator provided by the embodiments of the present disclosure further includes a second insulating layer located between the first heat dissipation layer and the wire routing layer. A material of the second insulating layer is an inorganic material, and a pattern of the second insulating layer is the same as a pattern of the first heat dissipation layer.

In one possible implementation, in the above piezoelectric actuator provided by the embodiments of the present disclosure, a material of the second insulating layer includes SiO₂, Al₂O₃ or Si₃N₄.

In one possible implementation, the above piezoelectric actuator provided by the embodiments of the present disclosure further includes a bonding electrode arranged on the same layer as the first electrode. The bonding electrode is arranged close to an edge of the base substrate. The bonding electrode is configured to connect a driving voltage input end. A voltage signal input by the driving voltage input end is an alternating voltage signal. The other end of the wire route is electrically connected to the bonding electrode through a fourth via hole formed in the first heat dissipation layer and the first insulating layer.

The above piezoelectric actuator provided by the embodiments of the present disclosure further includes a lead electrode arranged on the same layer as the first electrode. The lead electrode is electrically connected to the first electrode. The lead electrode is configured to connect a ground voltage input end, and a voltage signal input by the ground voltage input end is a grounding voltage signal.

In one possible implementation, in the above piezoelectric actuator provided by the embodiments of the present disclosure, a plurality of piezoelectric units are provided, the plurality of piezoelectric units are arranged on a side of the base substrate in an array, the first electrodes of all the piezoelectric units communicate with one another, and the second electrodes of all the piezoelectric units are connected to the same wire route in the wire routing layer.

In one possible implementation, in the above piezoelectric actuator provided by the embodiments of the present disclosure, a plurality of piezoelectric units are provided, the plurality of piezoelectric units are arranged on a side of the base substrate in an array, the first electrodes of all the piezoelectric units communicate with one another, and the second electrodes of all the piezoelectric units are connected to different wire routes in the wire routing layer.

In one possible implementation, in the above piezoelectric actuator provided by the embodiments of the present disclosure, a plurality of piezoelectric units are provided, the plurality of piezoelectric units are arranged on a side of the base substrate in an array, the first electrodes of all the piezoelectric units communicate with one another, and the second electrodes of the piezoelectric units located on the same column are connected to the same wire route in the wire routing layer.

In one possible implementation, in the above piezoelectric actuator provided by the embodiments of the present disclosure, materials of the first electrode and that of the second electrode are both transparent conducting materials.

In one possible implementation, in the above piezoelectric actuator provided by the embodiments of the present disclosure, an orthographic projection of the wire route on the base substrate at least has an overlapping region with an orthographic projection of an edge region of the second electrode on the base substrate, and the first heat dissipation layer has the plurality of first via holes correspondingly in the overlapping region.

In one possible implementation, in the above piezoelectric actuator provided by the embodiments of the present disclosure, the orthographic projection of the wire route on the base substrate further has an overlapping region with an orthographic projection of a central region of the second electrode on the base substrate, a shape of the wire route is of a grid structure, and the first heat dissipation layer below each grid line of the grid structure has the plurality of first via holes.

In one possible implementation, in the above piezoelectric actuator provided by the embodiments of the present disclosure, a material of the wire route is Ti/Ni/Au, Ti/Au or Ti/Al/Ti.

In one possible implementation, in the above piezoelectric actuator provided by the embodiments of the present disclosure, a thickness of the piezoelectric layer is 500 nm-2000 nm.

In one possible implementation, in the above piezoelectric actuator provided by the embodiments of the present disclosure, a material of the piezoelectric layer includes at least one of lead zirconate titanate, aluminum nitride, zinc oxide, barium titanate, lead titanate, potassium niobate, lithium niobate, lithium tantalate, or lanthanum gallium silicate.

Accordingly, embodiments of the present disclosure further provide a haptics apparatus, including the above piezoelectric actuator provided by any one of the embodiments of the present disclosure.

### BRIEF DESCRIPTION OF THE DRAWINGS

FIG. 1 is a schematic diagram of a relation between temperature during vibration of a piezoelectric actuator and vibration time.

FIG. 2 is schematic structural diagram of a piezoelectric actuator provided in the related art.

FIG. 3 is a schematic planar structural diagram of a piezoelectric actuator provided by an embodiment of the present disclosure.

FIG. 4-FIG. 23 are schematic structural diagrams of sections of a piezoelectric actuator provided by embodiments of the present disclosure.

FIG. 24 is a schematic planar diagram of a wire route arranged above a piezoelectric unit.

FIG. 25 is another planar diagram of a wire route arranged above a piezoelectric unit.

FIG. 26 is a schematic enlarged diagram of a dotted frame in FIG. 25.

### DETAILED DESCRIPTION OF THE EMBODIMENTS

In order to make objectives, technical solutions and advantages of the present disclosure clearer, the technical solutions of embodiments of the present disclosure will be clearly and completely described below in combination with the accompanying drawings of the embodiments of the present disclosure. Apparently, the described embodiments are some embodiments of the present disclosure, rather than all the embodiments. Under the condition of no conflict, the embodiments of the present disclosure and features in the embodiments may be combined with one another. Based on the described embodiments of the present disclosure, all other embodiments obtained by those of ordinary skill in the art without creative efforts fall within the protection scope of the present disclosure.

Unless otherwise defined, technical or scientific terms used herein shall have the ordinary meaning as understood by those of ordinary skill in the art to which the present disclosure belongs. Similar words such as “comprise” or “include” used in the present disclosure mean that elements or items appearing before the words encompass elements or items listed after the words and their equivalents, but do not exclude other elements or items. Similar words such as “connect” or “link” are not limited to physical or mechanical connection, but may include electrical connection, whether direct or indirect. “Inner”, “outer”, “upper”, “lower”, etc. are only used to indicate a relative positional relationship, and when an absolute position of a described object changes, the relative positional relationship may also change accordingly.

It should be noted that dimensions and shapes of figures in the accompanying drawings do not reflect a real scale, and are only intended to illustrate contents of the present disclosure. The same or similar reference numerals refer to the same or similar elements or elements having the same or similar functions throughout.

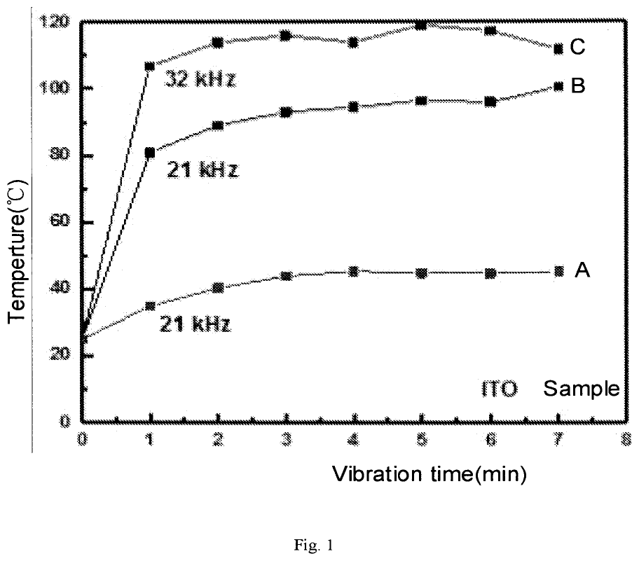

Thin film piezoelectric materials have high dielectric constant and transparency characteristics, making them ideal for vibrator structures integrated with a screen. Among thin film piezoelectric materials, lead zirconate titanate piezoelectric ceramics (PZT) are currently used more frequently due to their excellent piezoelectric performance. A structure of a PZT-based piezoelectric actuator is designed for physical vibration. During vibration, because of vibration of substrate lattices/molecules, heat energy will surely be emitted to cause the temperature of the piezoelectric device to rise. As shown in FIG. 1, FIG. 1 is a change curve of a temperature during vibration of the piezoelectric actuator with the vibration time. A curve A is a change curve of the temperature between piezoelectric devices with the vibration time at a vibration frequency of 21 KHz. A curve B is a change curve of the temperature above the piezoelectric device with the vibration time at a vibration frequency of 21 KHz. A curve C is a change curve of the temperature above the piezoelectric device with the vibration time at a vibration frequency of 32 KHz. It can be seen that with the increase of the vibration time, the temperature during vibration of the piezoelectric actuator will increase significantly, and this temperature will deteriorate breakdown characteristics (internal resistance) of the piezoelectric device and the resonant frequency of a resonator, thereby damaging the performance of the piezoelectric device and affecting the characteristics of the final tactile experience.

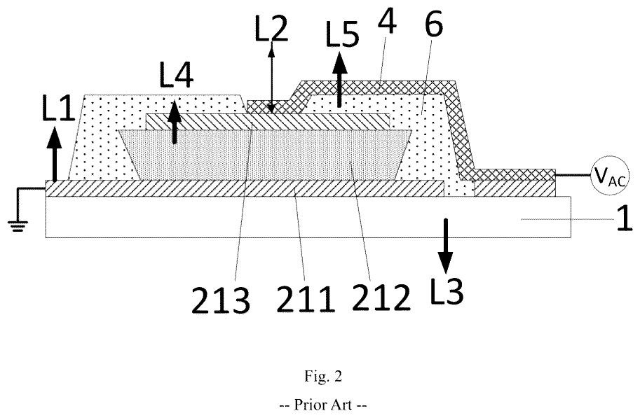

The inventor of this case found that increase of the temperature during vibration of the piezoelectric actuator is particularly related to heating of a circuit wire route in the piezoelectric actuator. As shown in FIG. 2, which is a schematic structural diagram of a piezoelectric actuator in the related art, the piezoelectric actuator includes a first electrode 211, a piezoelectric layer 212, a second electrode 213, an insulating layer 6 and a wire routing layer 4 laminated sequentially on the base substrate 1. The wire routing layer 4 is electrically connected to the second electrode 213 through a via hole penetrating through the insulating layer 6. In order to integrate the piezoelectric actuator in a screen display device, the first electrode 211 and the second electrode 213 are generally made of transparent conducting materials such as ITO, the base substrate 1 is generally a glass substrate, and the wire routing layer 4 is generally a grid-like metal. When the piezoelectric actuator vibrates, the ITO, the wire routing layer, etc. will all generate heat. Due to the low thermal conductivity of air, glass, ITO, the organic insulating layer, etc., the heat in ITO-air (an arrow L1), wire routing layer-air (an arrow L2), base substrate-air (an arrow L3), ITO-insulating layer (an arrow L4) and insulating layer-wire routing layer (an arrow L5) cannot be effectively exported, resulting in an increase of the temperature of the piezoelectric actuator.

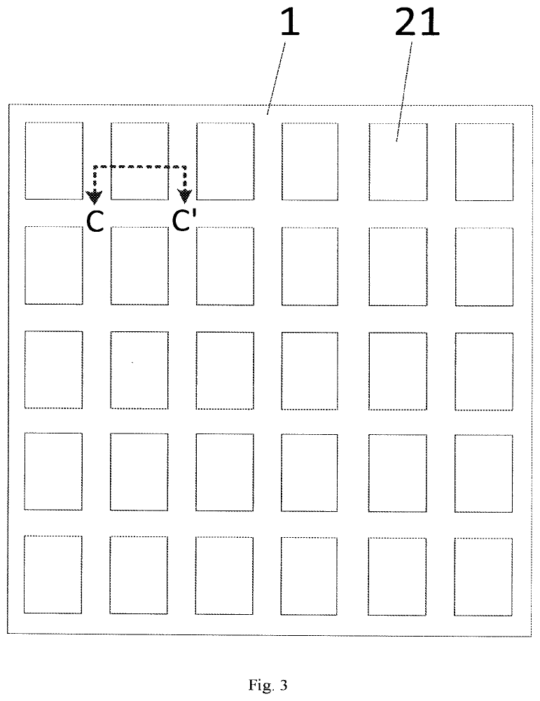

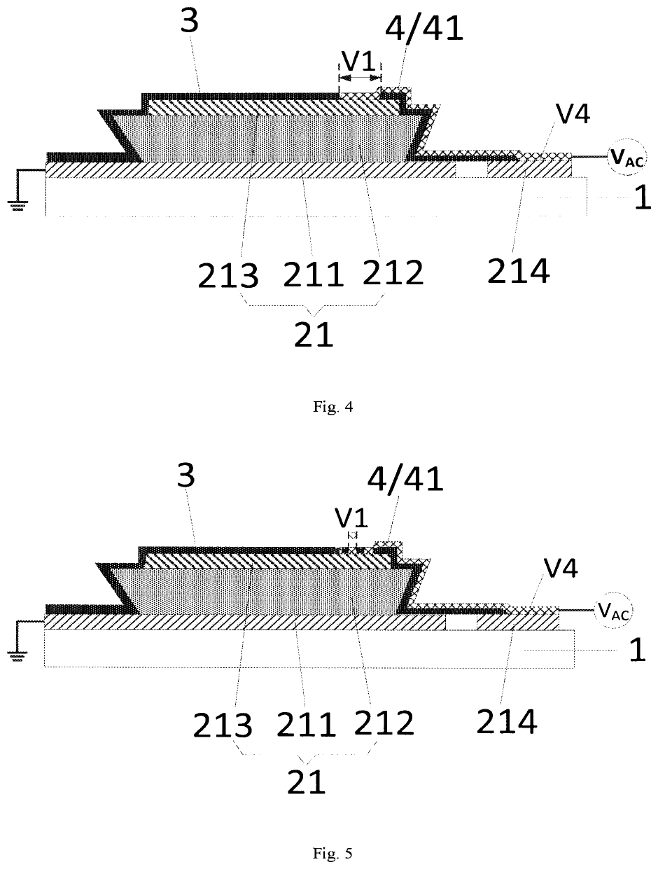

In view of this, embodiments of the present disclosure provide a piezoelectric actuator. As shown in FIG. 3-FIG. 5, FIG. 3 is a schematic top view of the piezoelectric actuator, and FIG. 4 and FIG. 5 are respectively schematic diagrams of sections in a direction CC′ in FIG. 3.

The piezoelectric actuator may include a base substrate 1, a piezoelectric device 2, a first heat dissipation layer 3, and a wire routing layer 4.

The piezoelectric device 2 is located on the base substrate 1. The piezoelectric device 2 includes at least one piezoelectric unit 21. Each piezoelectric unit 21 includes a first electrode 211, a piezoelectric layer 212 and a second electrode 213 which are laminated on the base substrate in sequence. Embodiments of the present disclosure take a plurality of piezoelectric units 21 arranged in an array as an example.

The first heat dissipation layer 3 is located on a side of the piezoelectric device 2 facing away from the base substrate 1. The first heat dissipation layer 3 is provided with a first via hole V1. An orthographic projection of the first via hole V1 on the base substrate 1 overlaps an orthographic projection of the second electrode 213 on the base substrate 1.

The wire routing layer 4 is located on a side of the first heat dissipation layer 3 facing away from the base substrate 1. The wire routing layer 4 includes a wire route 41. One end of the wire route 41 is electrically connected to the second electrode 213 through the first via hole V1.

In the above piezoelectric actuator provided by the embodiments of the present disclosure, by arranging the first heat dissipation layer 3 between the piezoelectric device 2 and the wire routing layer 4, the first heat dissipation layer 3 may improve the problem of heating at a top of the piezoelectric actuator, the transverse heat conduction capacity is improved, heat generated by the piezoelectric actuator during vibration is prevented from accumulating at the top, and characteristics of a temperature effect may be effectively lowered. Furthermore, the first heat dissipation layer 3 provided by the embodiments of the present disclosure may adopt an insulating material, so manufacturing of one insulating layer (manufactured between the second electrode 213 and the wire routing layer 4 in the related art) may be omitted, and a thickness of the piezoelectric actuator may be reduced.

In implementations, the base substrate may be a substrate made of glass, or a substrate made of silicon or SiO₂, or a substrate made of sapphire, or a substrate made of a metal wafer, which is not limited here. Those skilled in the art may arrange the base substrate according to actual application needs.

In implementations, in the above piezoelectric actuator provided by the embodiments of the present disclosure, the first heat dissipation layer may be of an integrated structure. For example, in manufacturing the first heat dissipation layer, an entire layer of heat dissipation thin film may be deposited on the piezoelectric device, and then the heat dissipation thin film is patterned to obtain the first heat dissipation layer provided with a plurality of first via holes overlapping the second electrodes in all the piezoelectric units.

In implementations, in the above piezoelectric actuator provided by the embodiments of the present disclosure, the first heat dissipation layer may include a plurality of first heat dissipation parts in one-to-one correspondence to the piezoelectric units. Each heat dissipation part is provided with the first via hole. For example, in manufacturing of the first heat dissipation layer, the entire layer of heat dissipation thin film may be deposited on the piezoelectric device, and then a single-time patterning process is performed on the heat dissipation thin film to obtain the plurality of first heat dissipation parts in one-to-one correspondence to all the piezoelectric units. The first heat dissipation parts are provided with a plurality of first via holes overlapping the second electrodes of the piezoelectric units.

Preferably, in order to export all heat generated by the piezoelectric actuator during vibration as much as possible and to simplify a manufacturing process, the first heat dissipation layer in the embodiments of the present disclosure adopts an integrated structure.

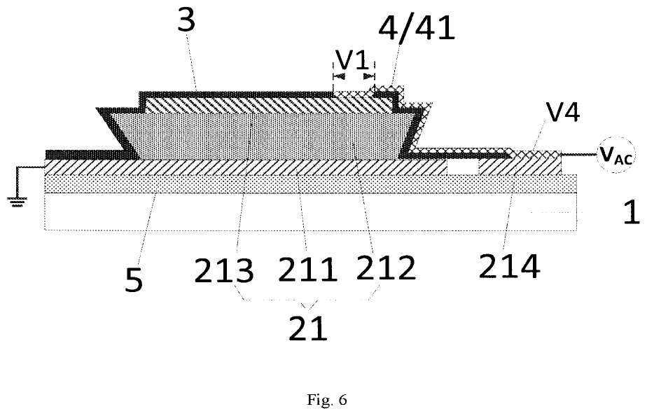

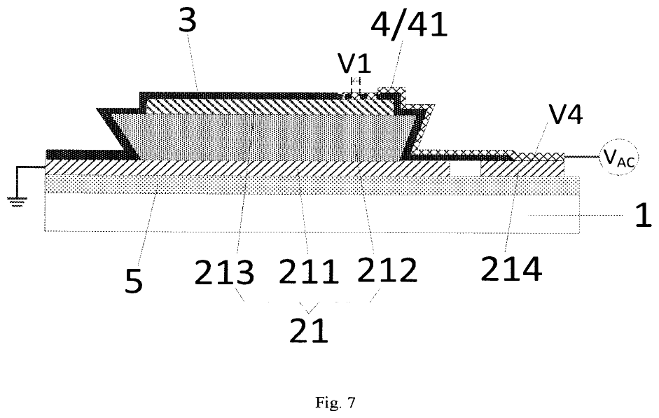

In implementations, as shown in FIG. 6 and FIG. 7, the above piezoelectric actuator provided by the embodiments of the present disclosure further includes a second heat dissipation layer 5 located between the piezoelectric unit 21 and the base substrate 1. The second heat dissipation layer 5 may export heat generated by the first electrode 211, thus the transverse heat conduction capacity of the first electrode 211 is improved, the heat generated by the piezoelectric actuator during vibration is prevented from accumulating at the first electrode 211, and characteristics of the temperature effect may be further lowered.

In implementations, in the above piezoelectric actuator provided by the embodiments of the present disclosure, the second heat dissipation layer may be of an entire-surface structure. For example, in manufacturing the second heat dissipation layer, an entire layer of second heat dissipation layer may be deposited between the piezoelectric unit and the base substrate, and patterning is not needed.

Alternatively, in implementations, the second heat dissipation layer may include a plurality of second heat dissipation parts in one-to-one correspondence to the piezoelectric units. For example, in manufacturing the second heat dissipation layer, an entire layer of heat dissipation thin film may be deposited between the piezoelectric units and the base substrate, and then patterning is performed on the heat dissipation thin film to obtain the plurality of second heat dissipation parts in one-to-one correspondence to the piezoelectric units.

Preferably, in order to export all heat generated by the piezoelectric actuator during vibration as much as possible, the second heat dissipation layer in the embodiments of the present disclosure adopts an entire-surface structure.

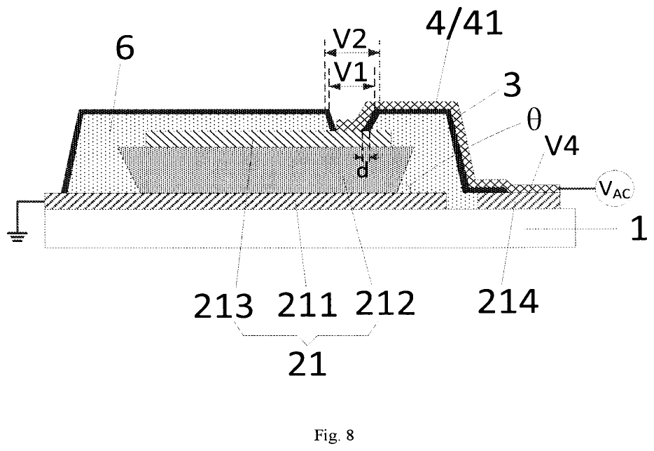

In implementations, in order to prevent the first dissipation layer from influencing performance of the piezoelectric device, as shown in FIG. 8-FIG. 11, the above piezoelectric actuator provided by the embodiments of the present disclosure further includes a first insulating layer 6 located between the piezoelectric device 2 and the first heat dissipation layer 3. The first insulating layer 6 is provided with a second via hole V2. An orthographic projection of the second via hole V2 on the base substrate 1 at least partially overlaps the orthographic projection of the first via hole V1 on the base substrate 1.

In implementations, in the above piezoelectric actuator provided by the embodiments of the present disclosure, as shown in FIG. 8-FIG. 11, a material of the first insulating material 6 is an organic material. For example, a manufacturing process of the piezoelectric layer 212 (for example, a PZT material) generally includes dry etching and wet etching. When a wet etching process is adopted, the piezoelectric layer 212 is prone to forming a chamfer structure, and a chamfer θ is generally 60° to 85°. When a dry etching process is adopted to manufacture the piezoelectric layer 212, a chamfer θ is generally 85° to 95°. It should be noted that, the embodiments of the present disclosure takes manufacturing the piezoelectric layer 212 by using the wet etching process as an example, so the chamfer θ is generally 60° to 85°. Due to the existence of the chamfer θ, the wire routing layer 4 is prone to line breakage. Thus he chamfer θ of the piezoelectric layer 212 needs to be filled. Embodiments of the present disclosure adopt an organic insulating layer 6 between the wire routing layer 4 and the second electrode 213 to fill the chamfer θ of the piezoelectric layer 212. An effect of the organic insulating layer 6 is to cover part of the first electrode 211 so as to prevent the wire routing layer 4 and other structures from short circuit, and to fill the chamfer of the piezoelectric layer 212 so as to prevent the wire routing layer 4 manufactured subsequently from breakage.

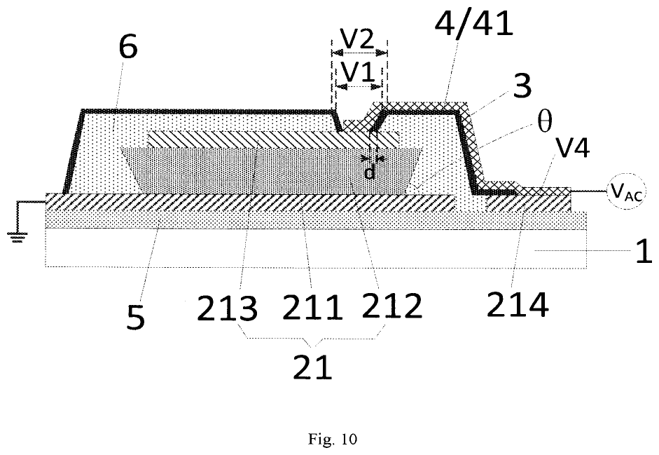

In implementations, in the above piezoelectric actuator provided by the embodiments of the present disclosure, as shown in FIG. 8 and FIG. 10, the orthographic projection of the second via hole V2 on the base substrate 1 is substantially coincided with the orthographic projection of the first via hole V1 on the base substrate. The first heat dissipation layer 3 covers a side wall of the second via hole V2 and extends to make contact with the second electrode 213. Due to the influence of a manufacturing process, a section of the second via hole V2 in a thickness direction of the piezoelectric actuator is usually of an inverted trapezoidal structure. Through the arrangement that the first heat dissipation layer 3 covers the side wall of the second via hole V2 and extends to make contact with the second electrode 213, the first heat dissipation layer 3 has a buffering effect in the second via hole V2, so that the wire routing layer 4 manufactured subsequently is prevented from line breakage at the second via hole V2.

In implementations, in the above piezoelectric actuator provided by the embodiments of the present disclosure, as shown in FIG. 8 and FIG. 10, at the same side wall of the second via hole V2, a contact boundary between the first heat dissipation layer 3 and the second electrode 213 is a first boundary, a contact boundary between the first insulating layer 6 and the second electrode 213 is a second boundary, and a distance ‘d’ between the first boundary and the second boundary is larger than 30% of a thickness of the piezoelectric layer 212 and smaller than 60% of the thickness of the piezoelectric layer 212. For example, the thickness of the piezoelectric layer 212 is usually 500 nm-2000 nm, such as 500 nm, 600 nm, 700 nm, 800 nm, 900 nm, 1000 nm, 1100 nm, 1200 nm, 1300 nm, 1400 nm, 1500 nm, 1600 nm, 1700 nm, 1800 nm, 1900 nm, or 2000 nm. For example, to take the thickness of the piezoelectric layer 212 being 600 nm as an example, ‘d’ is larger than 180 nm and smaller than 360 nm; to take the thickness of the piezoelectric layer 212 being 900 nm as an example, ‘d’ is larger than 270 nm and smaller than 540 nm; to take the thickness of the piezoelectric layer 212 being 1500 nm as an example, ‘d’ is larger than 450 nm and smaller than 900 nm; etc.

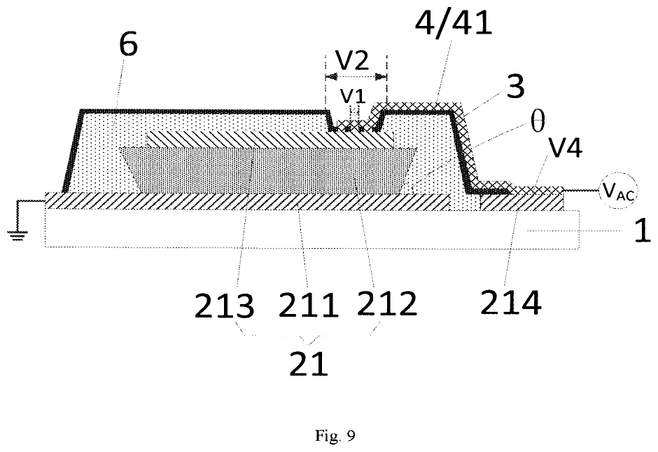

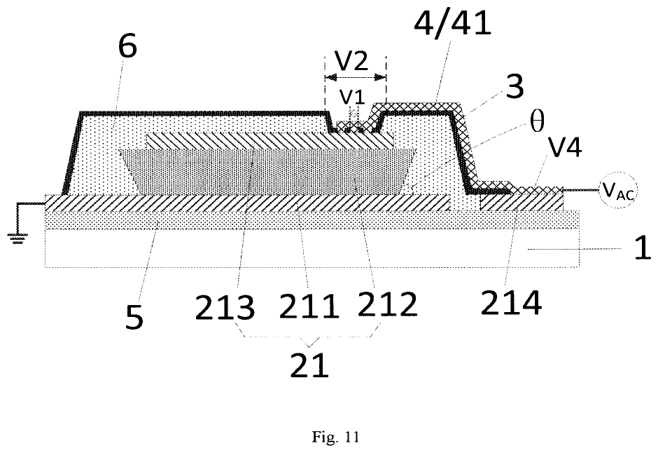

In implementations, a material of the wire routing layer is usually a metal material. A material of the second electrode is usually indium tin oxide (ITO). Adhesion between metal and ITO is poor. In order to prevent the problem that the wire routing layer is stripped off from the second electrode and thus cannot perform electrical signal transmission, in the above piezoelectric actuator provided by the embodiments of the present disclosure, as shown in FIG. 9 and FIG. 11, the first heat dissipation layer 3 covers the side wall of the second via hole V2 and covers the second electrode 213 exposed by the second via hole V2. The part of the first heat dissipation layer 3 covering the second electrode 213 is provided with at least one first via hole V1. The wire routing layer 4 is electrically connected to the second electrode 213 through the first via hole V1 and the second via hole V2. In this way, a part of the wire routing layer 4 is in contact with the first heat dissipation layer 3 on the exposed second electrode 213, and another part of the wire routing layer 4 is electrically with the second electrode 213 through the first via hole V1 and the second via hole V2. Because adhesion between the wire routing layer 4 and the first heat dissipation layer 3 is relatively strong, the adhesion between the wire routing layer 4 and the second electrode 213 may be improved on a basis that the wire routing layer 4 is electrically connected with the second electrode 213.

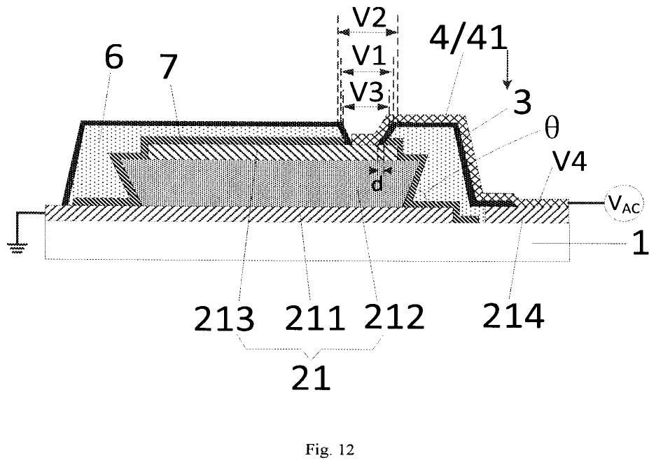

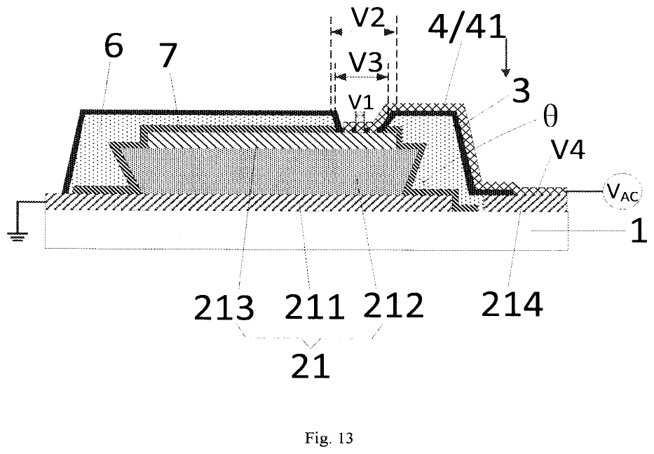

In implementations, as shown in FIG. 12-FIG. 15, the above piezoelectric actuator provided by the embodiments of the present disclosure further includes a third heat dissipation layer 7 located between the first insulating layer 6 and the piezoelectric unit 21. The third heat dissipation layer 7 is provided with a third via hole V3. The third via hole V3, the first via hole V1 and the second via hole V2 at least partially overlap one another. The third heat dissipation layer 7 may export the heat generated by the second electrode 213, thus the heat generated by the piezoelectric actuator during vibration is prevented from accumulating at the second electrode 213, and characteristics of the temperature effect may be further lowered.

In implementations, in the above piezoelectric actuator provided by the embodiments of the present disclosure, the third heat dissipation layer may be of an integrated structure. For example, in manufacturing the third heat dissipation layer, an entire layer of heat dissipation thin film may be deposited between the first insulating layer and the piezoelectric device, and then patterning is performed on the heat dissipation thin film to obtain the third heat dissipation layer provided with the third via hole which at least partially overlaps the first via hole and the second via hole.

In implementations, in the above piezoelectric actuator provided by the embodiments of the present disclosure, the third heat dissipation layer may include a plurality of third heat dissipation parts in one-to-one correspondence to the piezoelectric units. Each third heat dissipation part is provided with the third via hole. For example, in manufacturing of the third heat dissipation layer, the entire layer of heat dissipation thin film may be deposited between the first insulating layer and the piezoelectric device, and then a one-time patterning process is performed on the heat dissipation thin film to obtain the plurality of third heat dissipation parts in one-to-one correspondence to all the piezoelectric units. Each third heat dissipation part is provided with the third via hole.

Preferably, in order to export all heat generated by the piezoelectric actuator during vibration as much as possible, the third heat dissipation layer in the embodiments of the present disclosure adopts an integrated structure.

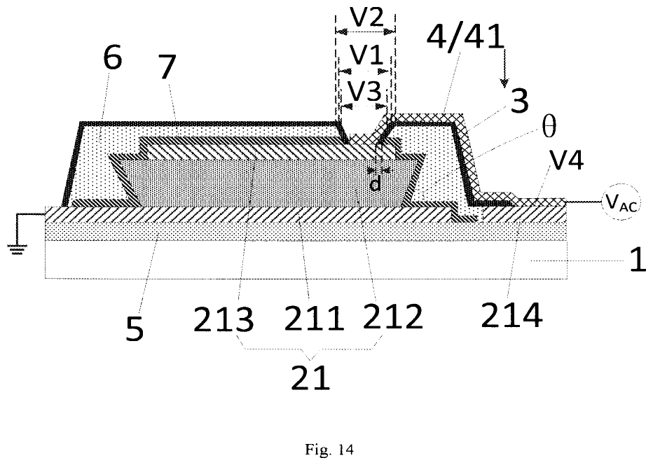

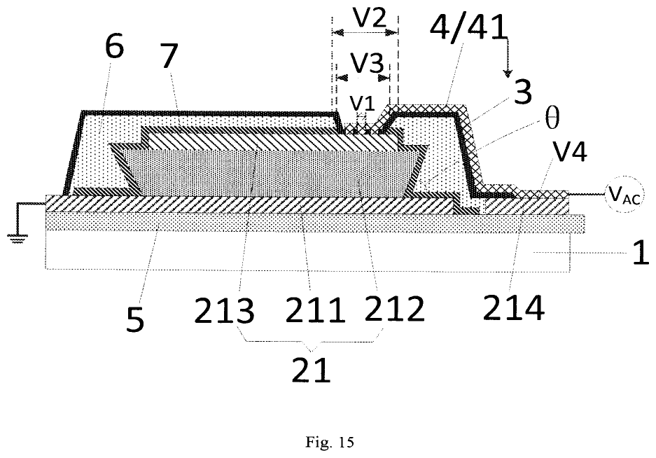

In implementations, in order to export all the heat generated by the piezoelectric actuator provided by the embodiments of the present disclosure during vibration as much as possible, as shown in FIG. 14 and FIG. 15, the first heat dissipation layer 3, the second heat dissipation layer 5 and the third heat dissipation layer 7 are all arranged in the piezoelectric actuator, so that the best heat conduction effect may be achieved and vibration performance of the piezoelectric device is improved.

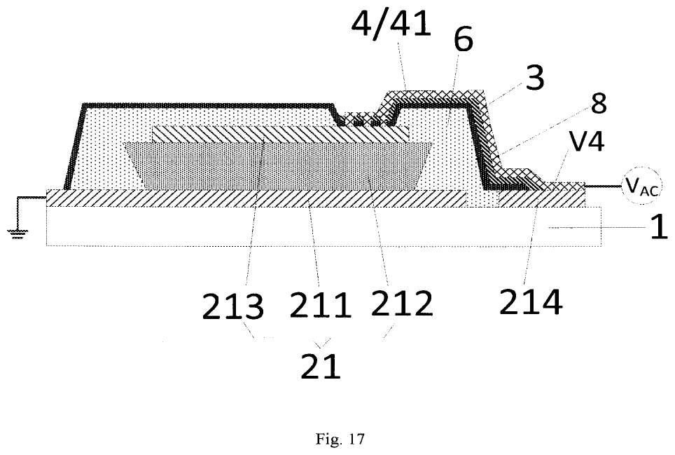

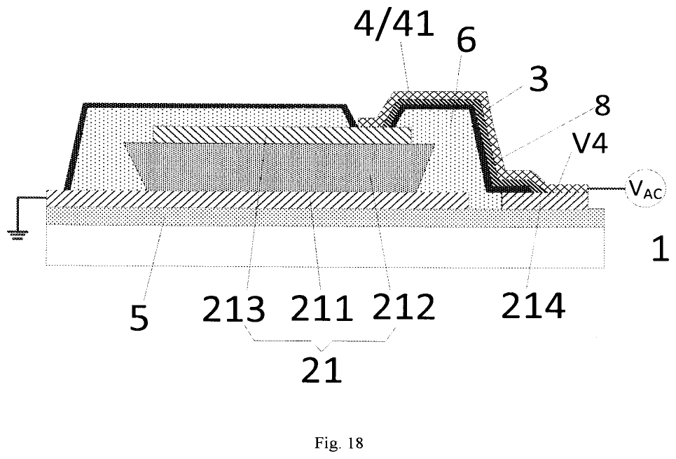

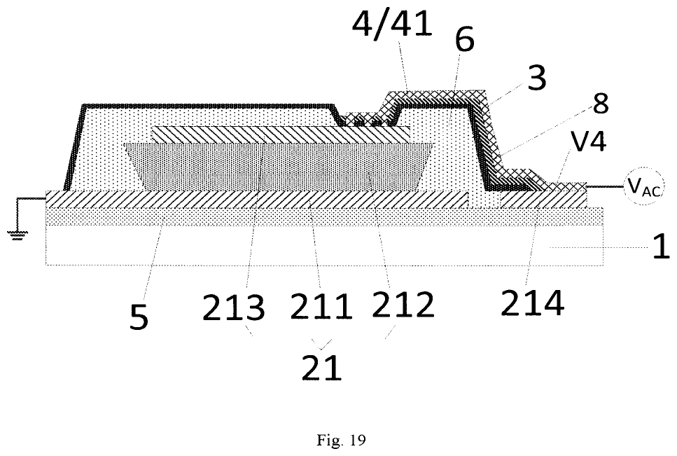

In implementations, in the above piezoelectric actuator provided by the embodiments of the present disclosure, as shown in FIG. 4-FIG. 19, a material of the first heat dissipation layer 3 may be an insulating material. As shown in FIG. 6, FIG. 7, FIG. 10, FIG. 11, FIG. 14 and FIG. 15, a material of the second heat dissipation layer 5 may be an insulating material. As shown in FIG. 12-FIG. 15, a material of the third heat dissipation layer 7 may be an insulating material.

Further, the piezoelectric actuator is usually combined with a display device to realize haptic reproduction. In order to improve a transmittance of the piezoelectric actuator, the material of the first heat dissipation layer 3, the material of the second heat dissipation layer 5 and the material of the third heat dissipation layer 7 may all be transparent insulating materials.

For example, thermal balance in the piezoelectric actuator is related to a heat dissipation feature: T=(Q/t)*L/(A*k). Here ‘k’ is heat conductivity, Q is heat, ‘t’ is time, L is length, A is area and Tis temperature. Q, t, L and A are all constants. If the temperature T of the piezoelectric actuator needs to be small enough (rapid heat conduction--no heat generated), the heat conductivity ‘k’ needs to be as large as possible. Therefore, the materials of the first heat dissipation layer 3, the second heat dissipation layer 5 and the third heat dissipation layer 7 may be transparent insulating materials with high heat conductivity. Therefore, in the above piezoelectric actuator provided by the embodiments of the present disclosure, the transparent insulating materials may include at least one of AlN, Al₂O₃ or Si₃N₄. For example, heat conductivity of AlN is 321 W/(m·K), heat conductivity of Al₂O₃ is 60 W/(m·K), and heat conductivity of Si₃N₄ is 80 W/(m·K). A preferable transparent insulating material in the embodiments of the present disclosure is AlN.

Because adhesion between AlN, Al₂O₃ or Si₃N₄ and the wire routing layer 4 is stronger than adhesion between the organic first insulating layer 6 and the wire routing layer 4, as shown in FIG. 4-FIG. 15, the first heat dissipation layer 3 may further be reused as an adhering layer to enhance the adhesion between the wire routing layer 4 and the base substrate 1, thus preventing the wire routing layer 4 from stripping.

In implementations, because the piezoelectric actuator is usually combined with the display device to realize haptic reproduction, in order to prevent the heat dissipation layers from influencing the transmittance, in the above piezoelectric actuator provided by the embodiments of the present disclosure, as shown in FIG. 4-FIG. 15, a thickness of the first heat dissipation layer 3 may be 300 nm-2000 nm, a thickness of the second heat dissipation layer 5 may be 300 nm-2000 nm, and a thickness of the third heat dissipation layer 7 may be 300 nm-2000 nm. In this way, heat dissipation performance of all the heat dissipation layers may be ensured while the transmittance is not influenced.

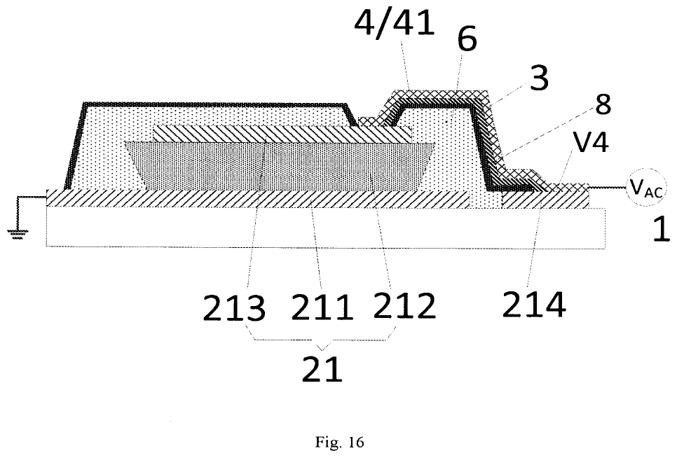

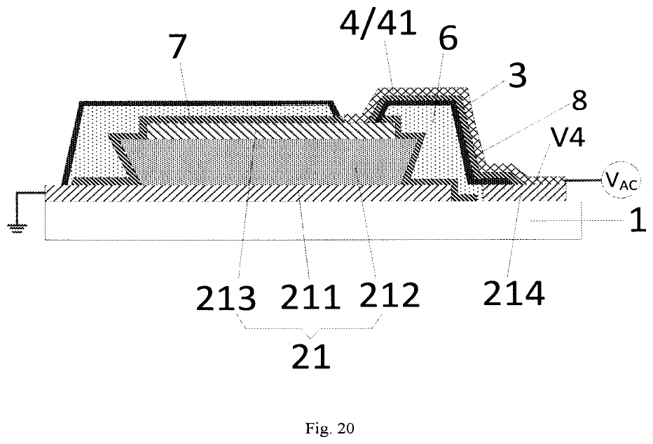

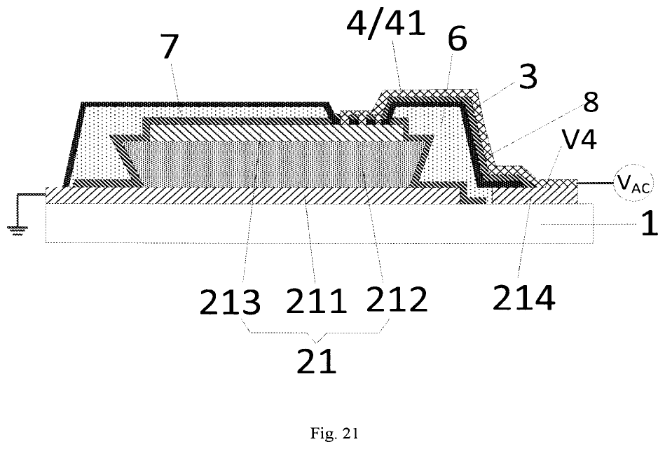

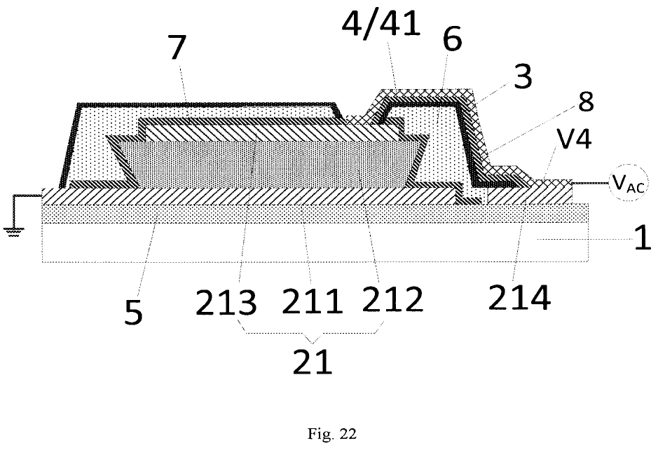

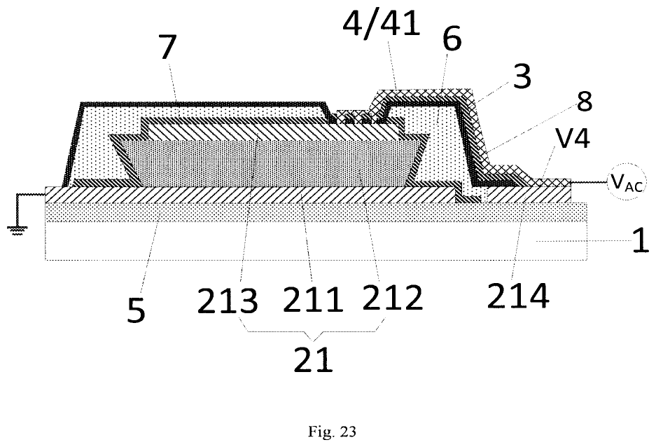

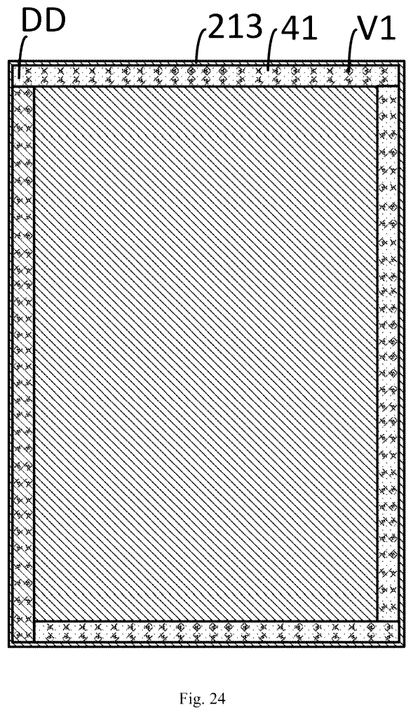

In implementations, in order to further improve the adhesion between the wire routing layer and the second electrode and thus prevent the wire routing layer from stripping, the above piezoelectric actuator provided by the embodiments of the present disclosure, as shown in FIG. 16-FIG. 23, further includes a second insulating layer 8 located between the first heat dissipation layer 3 and the wire routing layer 4. A material of the second insulating layer 8 is an inorganic material, and a pattern of the second insulating layer 8 is the same as a pattern of the first heat dissipation layer 4.

In implementations, in the above piezoelectric actuator provided by the embodiments of the present disclosure, as shown in FIG. 16-FIG. 23, a material of the second insulating layer 8 may include but is not limited to SiO₂, Al₂O₃ or Si₃N₄.

In implementations, the above piezoelectric actuator provided by the embodiments of the present disclosure, as shown in FIG. 4-FIG. 23, further includes: a bonding electrode 214 arranged on the same layer as the first electrode 211. The bonding electrode 214 is arranged close to an edge of the base substrate 1. The bonding electrode 214 is configured to connect a driving voltage input end. A voltage signal input by the driving voltage input end is an alternating voltage signal. As shown in FIG. 8-FIG. 15, the other end of the wire route 41 is electrically connected to the bonding electrode 214 through a fourth via hole V4 formed in the first heat dissipation layer 3 and the first insulating layer 6. As shown in FIG. 16-FIG. 23, the other end of the wire route 41 is electrically connected to the bonding electrode 214 through the fourth via hole V4 formed in the first heat dissipation layer 3, the first insulating layer 6 and the second insulating layer 8.

In implementations, the above piezoelectric actuator provided by the embodiments of the present disclosure, as shown in FIG. 4-FIG. 23, further includes: a lead electrode (not shown) arranged on the same layer as the first electrode 211. The lead electrode is electrically connected to the first electrode 211. The lead electrode is configured to connect a ground voltage input end. A voltage signal input by the ground voltage input end is a grounding voltage signal. In implementations, the grounding voltage signal is input into the first electrode 211 through the ground voltage input end, an alternating voltage signal (V_{AC}) is loaded to the second electrode 213 through the driving voltage input end, and an alternating electric field may be formed between the first electrode 211 and the second electrode 213. A frequency of the alternating electric field is the same as a frequency of the alternating voltage signal. Under an effect of the alternating electric field, the piezoelectric layer 212 is deformed and generates a vibration signal, and a frequency of the vibration signal is the same as the frequency of the alternating electric field. When the frequency of the vibration signal is close to or equal to an inherent frequency of the base substrate 1, the base substrate 1 resonates, an amplitude is enhanced, and a haptics signal is generated. When a finger touches a surface of the base substrate 1, the finger may obviously feel a change of friction. In practical applications, the friction on the surface of the base substrate 1 may be adjusted through resonance generated between the piezoelectric layer 212 and the base substrate 1, so that texture reproduction of an object is realized on the surface of the base substrate 1.

In embodiments, the first electrode 211, the bonding electrode 214 and the lead electrode may be made of the same material and be formed through the same patterning process.

In order to lower a risk of short circuit, with reference to FIG. 4-FIG. 23, an edge of the second electrode 213 may retract relative to an edge of the piezoelectric layer 212. In implementations, a retracting distance of the edge of the second electrode 213 relative to the edge of the piezoelectric layer 212 is larger than or equal to 100 micron and smaller than or equal to 500 micron. For example, the retracting distance may be 150 micron.

In order to further lower the risk of short circuit, the edge of the piezoelectric layer 212 may retract relative to an edge of the first electrode 211.

In implementations, in the above piezoelectric actuator provided by the embodiments of the present disclosure, as shown in FIG. 3-FIG. 23, a plurality of piezoelectric units 21 are provided. The plurality of piezoelectric units 21 are arranged on a side of the base substrate 1 in an array. The first electrodes 211 of all piezoelectric units 21 can communicate with one another. The second electrodes 213 of all piezoelectric units 21 can be connected to the same wire route 41 in the wire routing layer 4. In this way, overall driving of the piezoelectric actuator may be realized.

In implementations, in the above piezoelectric actuator provided by the embodiments of the present disclosure, as shown in FIG. 3-FIG. 23, a plurality of piezoelectric units 21 are provided. The plurality of piezoelectric units 21 are arranged on a side of the base substrate 1 in an array. The first electrodes 211 of all piezoelectric units 21 can communicate with one another. The second electrodes 213 of all piezoelectric units 21 are connected to different wire routes 41 in the wire routing layer 4. In this way, separate driving of each piezoelectric unit 21 may be realized, so a driving signal may be loaded merely on the piezoelectric unit 21 at a vibrating location, and power consumption may be lowered.

In implementations, in the above piezoelectric actuator provided by the embodiments of the present disclosure, as shown in FIG. 3-FIG. 23, a plurality of piezoelectric units 21 are provided. The plurality of piezoelectric units 21 are arranged on a side of the base substrate 1 in an array. The first electrodes 211 of all the piezoelectric units 21 can communicate with one another. The second electrodes 212 of the piezoelectric units 21 on the same column are connected to the same wire route in the wire routing layer 4. In this way, column driving may be realized. The driving signal may be loaded on the piezoelectric units 21 of a corresponding column, and power consumption may be lowered.

It should be noted that the embodiments of the present disclosure merely list several possible driving manners. Alternatively, there may be other driving manners based on actual needs, which all belong to the scope of protection of the embodiments of the present disclosure.

In implementations, because the piezoelectric actuator is usually combined with the display device to realize haptic reproduction, in order to improve the transmittance of the piezoelectric actuator, the materials of the first electrode and the second electrode are both transparent conducting materials.

In an implementation process, the first electrode and the second electrode may be made of indium tin oxide (ITO) or may be made of indium zinc oxide (IZO). Those skilled in the art may arrange the above first electrode and second electrode based on actual application needs, which is not limited here.

In implementations, in the above piezoelectric actuator provided by the embodiments of the present disclosure, as shown in FIG. 24 which is a planar diagram of a wire route 41 arranged above one piezoelectric unit 21, there is at least an overlapping region DD between an orthographic projection of the wire route 41 on the base substrate 1 and an orthographic projection of an edge region of the second electrode 213 on the base substrate 1. The first heat dissipation layer 3 is provided with a plurality of the first via holes V1 in the overlapping region DD. In this way, the wire route 41 does not cover a central region of the piezoelectric unit 21, and the transmittance may be improved.

It should be noted that, as shown in FIG. 24, the embodiments of the present disclosure is described by taking the orthographic projection of the wire route 41 on the base substrate 1 having the overlapping region DD with the edge regions on four sides of the second electrode 213 on the base substrate 1 as an example.

It should be noted that, FIG. 4-FIG. 23 all take that the orthographic projection of the first via hole V1 on the second electrode 213 is located in an edge region of the second electrode 213 as an example.

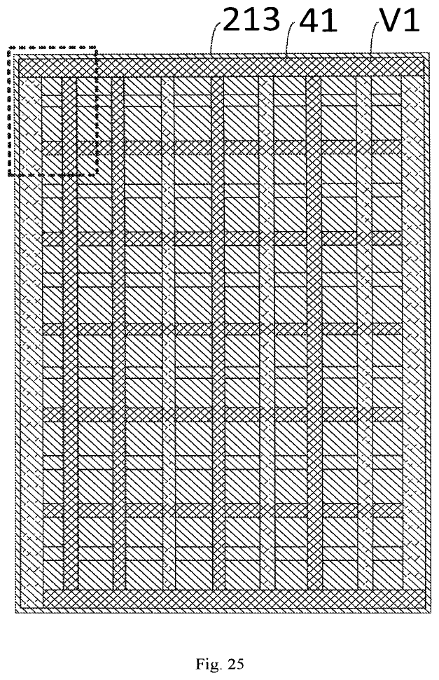

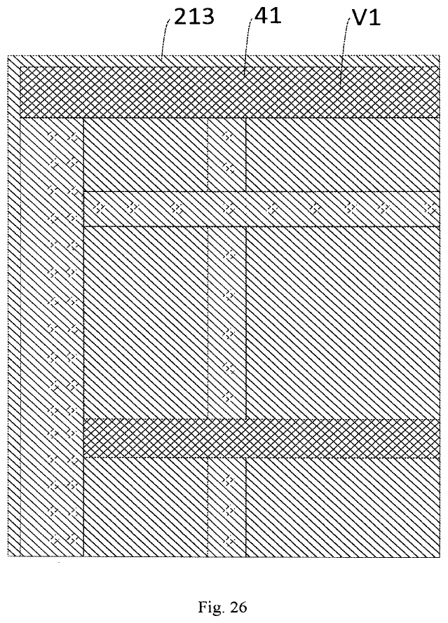

In implementations, when the materials of the first electrode and the second electrode are both transparent conducting materials (for example, ITO), because ITO is relatively large in resistance and will influence signal transmittance performance, in the above piezoelectric actuator provided by the embodiments of the present disclosure, as shown in FIG. 25 and FIG. 26, FIG. 25 being another planar diagram of a wire route 41 arranged above one piezoelectric unit 21 and FIG. 26 being a schematic enlarged diagram of a dotted frame in FIG. 25, the orthographic projection of the wire route 41 on the base substrate 1 further has an overlapping region with an orthographic projection of a central region of the second electrode 213 on the base substrate 1. A shape of the wire route 41 is of a grid structure. The first heat dissipation layer 3 below each grid line of the grid structure is provided with a plurality of first via holes V1. By arranging the wire route 41 to be of the grid structure, the transmittance will not be influenced by the grid structure. The first heat dissipation layer 3 below each grid line of the grid structure is provided with a plurality of first via holes V1, so the grid line may be electrically connected to the second electrode 213 through the first via holes V1, which is equivalent to the second electrode 213 being in parallel connection with all the grid lines, and the resistance of the second electrode 213 may be lowered. Therefore, the transmittance is not influenced, the resistance of the second electrode 213 may be lowered, and thus the signal transmittance performance may be improved.

In implementations, a material of the wire routing layer may be Ti/Ni/Au, where Ti may be 10 nm, Ni may be 400 nm, and Au may be 100 nm; or the material of the wire routing layer may be Ti/Au, where Ti may be 10 nm, and Au may be 400 nm; or the material of the wire routing layer may be Ti/Al/Ti, where Ti may be 10 nm, and Al may be 300 nm.

It should be noted that, the embodiments of the present disclosure is described by taking the materials of the first electrode and the second electrode both being transparent conducting materials as an example. Alternatively, in implementations, when there is no requirement on the transmittance of the piezoelectric actuator, the materials of the first electrode and the second electrode may also be both metal materials. The signal transmittance performance may be improved because the metal materials are low in resistance. Those skilled in the art may select the materials of the first electrode and the second electrode based on actual needs.

It should be noted that, the first electrode may include a plurality of patterned first electrodes or may be of an entire-surface structure. The first electrode includes a plurality of patterned second electrodes.

In implementations, a material of the piezoelectric layer may be lead zirconate titanate ((Pb(Zr, Ti)O₃) PZT), or at least one of aluminum nitride (AlN), zinc oxide (ZnO), barium titanate (BaTiO₃), lead titanate (PbTiO₃), potassium niobate (KNbO₃), lithium niobate (LiNbO₃), lithium tantalite (LiTaO₃), or lanthanum gallium silicate (La₃Ga₅SiO₁₄). The material of the piezoelectric layer may be selected based on actual using needs of those skilled in the art, and is not limited here. When PZT is used to manufacture the piezoelectric layer, because PZT has a high piezoelectric coefficient which ensures piezoelectric features of the corresponding piezoelectric actuator, the corresponding piezoelectric actuator may be applied to a haptics device. Because PZT is relatively high in light transmittance, when it is integrated to a display device, display quality of the display device is not affected.

The piezoelectric actuator provided by the embodiments of the present disclosure may be applied to medical care, automotive electronics, motion tracking systems and other fields, and is particularly applicable to the field of wearable devices, medical in vitro or in vivo monitoring and treatment, or the field of electronic skin of artificial intelligence. Particularly, the piezoelectric actuator may be applied to a brake block, a keyboard, a mobile terminal, a gaming console, a vehicle-mounted apparatus, or other apparatus that may generate vibration and have mechanical property.

Based on the same inventive concept, embodiments of the present disclosure further provide a haptics apparatus, including the above piezoelectric actuator provided by the embodiments of the present disclosure. Because a principle for solving a problem of the haptics apparatus is similar to that of the aforesaid piezoelectric actuator, for implementation of the haptics apparatus, reference may be made to implementation of the aforesaid piezoelectric actuator, and repetition will not be made. The haptics apparatus may be: a mobile phone, a tablet computer, a television, a display, a notebook computer, a digital photo frame, a navigator or any other product or component with a display or touch control function.

In implementations, the above haptics apparatus provided by the embodiments of the present disclosure may further include other functional structures known to those skilled in the art, and detailed description will not be made here.

In implementations, the haptics apparatus may be combined with a touch screen. A location of human touch may be determined through the touch screen, and therefore corresponding vibration waveform, amplitude and frequency are generated, thus realizing human-machine interaction. For another example, the location of human touch may be determined through the piezoelectric actuator in the haptics apparatus, and therefore corresponding vibration waveform, amplitude and frequency are generated, thus realizing human-machine interaction. Further, the haptics apparatus may also be applied to medical care, automotive electronics, motion tracking systems and other fields, which will not be described in detail here.

The embodiments of the present disclosure provide a piezoelectric actuator and a haptics apparatus. By arranging the first heat dissipation layer between the piezoelectric device and the wire routing layer, the first heat dissipation layer may improve the problem of heating at the top of the piezoelectric actuator, the transverse heat conduction capacity is improved, the heat generated by the piezoelectric actuator during vibration is prevented from accumulating at the top, and characteristics of the temperature effect may be effectively lowered. Furthermore, the first heat dissipation layer provided by the embodiments of the present disclosure may adopt the insulating material, so manufacturing of one insulating layer (manufactured between the second electrode and the wire routing layer in the related art) may be omitted, and the thickness of the piezoelectric actuator may be reduced.

Although the preferred embodiments of the present disclosure are described, those of skill in the art may otherwise make various modifications and variations to these embodiments once they are aware of the basic inventive concept. Therefore, the claims intend to include the preferred embodiments as well as all these modifications and variations falling within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalent technology, the present disclosure is also intended to include these modifications and variations.

1. A piezoelectric actuator, comprising:
a base substrate;
a piezoelectric device, located on the base substrate and comprising:
at least one piezoelectric unit, wherein each piezoelectric unit comprises:
a first electrode, a piezoelectric layer and a second electrode which are laminated on the base substrate in sequence;
a first heat dissipation layer, located on a side of the piezoelectric device facing away from the base substrate and provided with a first via hole, wherein an orthographic projection of the first via hole on the base substrate overlaps an orthographic projection of the second electrode on the base substrate; and
a wire routing layer, located on a side of the first heat dissipation layer facing away from the base substrate and comprising a wire route, wherein an end of the wire route is electrically connected to the second electrode through the first via hole.

2. The piezoelectric actuator according to claim 1, wherein:
the first heat dissipation layer is of an integrated structure; or
the first heat dissipation layer comprises:
a plurality of first heat dissipation parts in one-to-one correspondence to the piezoelectric units; wherein each of the heat dissipation parts is provided with the first via hole.

3. (canceled)

4. The piezoelectric actuator according to claim 1, further comprising:
a second heat dissipation layer between the piezoelectric unit and the base substrate.

5. The piezoelectric actuator according to claim 4, wherein:
the second heat dissipation layer is of an entire-surface structure; or
the second heat dissipation layer comprises:
a plurality of second heat dissipation parts in one-to-one correspondence to the piezoelectric units.

6. (canceled)

7. The piezoelectric actuator according to claim 1, further comprising:
a first insulating layer, located between the piezoelectric device and the first heat dissipation layer and provided with a second via hole;
wherein an orthographic projection of the second via hole on the base substrate at least partially overlaps the orthographic projection of the first via hole on the base substrate.

8. The piezoelectric actuator according to claim 7, wherein the orthographic projection of the second via hole on the base substrate is substantially coincided with the orthographic projection of the first via hole on the base substrate, and the first heat dissipation layer covers a side wall of the second via hole and extends to be in contact with the second electrode.

9. The piezoelectric actuator according to claim 8, wherein at a same side wall of the second via hole, a contact boundary between the first heat dissipation layer and the second electrode is a first boundary, a contact boundary between the first insulating layer and the second electrode is a second boundary, and a distance between the first boundary and the second boundary is larger than 30% of a thickness of the piezoelectric layer and smaller than 60% of the thickness of the piezoelectric layer.

10. The piezoelectric actuator according to claim 7, wherein the first heat dissipation layer covers a side wall of the second via hole and covers the second electrode exposed by the second via hole, a part of the first heat dissipation layer covering the second electrode is provided with at least one first via hole, and the wire routing layer is electrically connected to the second electrode through the second via hole and the first via hole.

11. The piezoelectric actuator according to claim 7, wherein a material of the first insulating layer is an organic material.

12. The piezoelectric actuator according to claim 7, further comprising:
a third heat dissipation layer, located between the first insulating layer and the piezoelectric unit and provided with a third via hole;
wherein the third via hole, the first via hole and the second via hole at least partially overlap one another.

13. The piezoelectric actuator according to claim 12, wherein:
the third heat dissipation layer is of an integrated structure; or
the third heat dissipation layer comprises:
a plurality of third heat dissipation parts in one-to-one correspondence to the piezoelectric units; wherein each of the third heat dissipation parts is provided with the third via hole.

14. (canceled)

15. The piezoelectric actuator according to claim 12, wherein:
a material of the first heat dissipation layer is an insulating material;
a material of the second heat dissipation layer is an insulating material; and
a material of the third heat dissipation layer is an insulating material.

16. (canceled)

17. The piezoelectric actuator according to claim 15, wherein a thickness of the first heat dissipation layer is 300 nm-2000 nm, a thickness of the second heat dissipation layer is 300 nm-2000 nm, and a thickness of the third heat dissipation layer is 300 nm-2000 nm; and
a thickness of the piezoelectric layer is 500 nm-2000 nm.

18. The piezoelectric actuator according to claim 1, further comprising:
a second insulating layer between the first heat dissipation layer and the wire routing layer;
wherein a material of the second insulating layer is an inorganic material, and a pattern of the second insulating layer is same as a pattern of the first heat dissipation layer.

19. (canceled)

20. The piezoelectric actuator according to claim 7, further comprising:
a bonding electrode arranged on a same layer as the first electrode; wherein the bonding electrode is arranged close to an edge of the base substrate and configured to connect a driving voltage input end, a voltage signal input by the driving voltage input end is an alternating voltage signal, and another end of the wire route is electrically connected to the bonding electrode through a fourth via hole formed in the first heat dissipation layer and the first insulating layer; and
a lead electrode arranged on the same layer as the first electrode, wherein the lead electrode is electrically connected to the first electrode and configured to connect a ground voltage input end, and a voltage signal input by the ground voltage input end is a grounding voltage signal.

21. The piezoelectric actuator according to claim 20, wherein:
a plurality of piezoelectric units are provided, the plurality of piezoelectric units are arranged on a side of the base substrate in an array, the first electrodes of all the piezoelectric units communicate with one another, and the second electrodes of all the piezoelectric units are connected to a same wire route in the wire routing layer; or
a plurality of piezoelectric units are provided, the plurality of piezoelectric units are arranged on a side of the base substrate in an array, the first electrodes of all the piezoelectric units communicate with one another, and the second electrodes of all the piezoelectric units are connected to different wire routes in the wire routing layer; or
a plurality of piezoelectric units are provided, the plurality of piezoelectric units are arranged on a side of the base substrate in an array, the first electrodes of all the piezoelectric units communicate with one another, and the second electrodes of the piezoelectric units on a same column are connected to a same wire route in the wire routing layer.

22. (canceled)

23. (canceled)

24. The piezoelectric actuator according to claim 21, wherein materials of the first electrode and that of the second electrode are both transparent conducting materials.

25. The piezoelectric actuator according to claim 24, wherein an orthographic projection of the wire route on the base substrate at least has an overlapping region with an orthographic projection of an edge region of the second electrode on the base substrate, and the first heat dissipation layer is provided with a plurality of the first via holes in the overlapping region.

26. The piezoelectric actuator according to claim 25, wherein the orthographic projection of the wire route on the base substrate further has an overlapping region with an orthographic projection of a central region of the second electrode on the base substrate, a shape of the wire route is of a grid structure, and the first heat dissipation layer below each grid line of the grid structure is provided with the plurality of first via holes.

27-29. (canceled)

30. A haptics apparatus, comprising the piezoelectric actuator according to claim 1.
